(19) United States
(12) Patent Application Publication
(10) Pub. No.: US 2024/0411227 A1
(43) Pub. Date: Dec. 12, 2024

(54) PHOTOLITHOGRAPHY METHOD AND METHOD OF MANUFACTURING SEMICONDUCTOR DEVICE USING THE SAME

(71) Applicant: Samsung Electronics Co., Ltd., Suwon-si (KR)

(72) Inventors: Sung Gap Im, Daejeon (KR); Seonkyu Shin, Suwon-si (KR); Sanghoon Ahn, Suwon-si (KR); Hanhum Park, Suwon-si (KR); Minkyung Cho, Suwon-si (KR); Chungryeol Lee, Daejeon (KR); Seungmin Lee, Daejeon (KR); Changhyeon Lee, Daejeon (KR); Sukwon Jang, Daejeon (KR)

(73) Assignee: KOREA ADVANCED INSTITUTE OF SCIENCE AND TECHNOLOGY, Daejeon (KR)

(21) Appl. No.: 18/427,044

(22) Filed: Jan. 30, 2024

(30) Foreign Application Priority Data
Jun. 8, 2023 (KR) 10-2023-0073767

(51) Int. Cl. G03F 7/11; G03F 7/031; G03F 7/16; H01L 21/027; H01L 21/308

(52) U.S. Cl. CPC G03F 7/11; G03F 7/031; G03F 7/167; G03F 7/168; H01L 21/0274; H01L 21/3081

(57) ABSTRACT

A photolithograph method is provided. The photolithograph method may include forming a photoresist pattern on a substrate and conformally forming a liner layer on the photoresist pattern, wherein the forming of the liner layer includes a deposition process of reacting an initiator and a monomer with each other, the monomer includes multiple bonds between carbon atoms, the initiator includes a material that forms a radical by thermal decomposition, a copolymer is formed by an initiating reaction between the radical and the monomer, and the liner layer includes the copolymer.

### CROSS-REFERENCE TO RELATED APPLICATION(S)

This U.S. non-provisional patent application claims priority under 35 U.S.C. § 119 to Korean Patent Application No. 10-2023-0073767, filed on Jun. 8, 2023, in the Korean Intellectual Property Office, the disclosure of which is hereby incorporated by reference in its entirety.

### BACKGROUND

The inventive concept relates to a photolithography method and a method of manufacturing a semiconductor device using the same, and more particularly, relates to a photolithography method including an initiated chemical vapor deposition process (iCVD).

Integrated circuit devices are used in various electronics industries for reasons including device miniaturization and/or reduced manufacturing costs and the like. Integrated circuit devices may include memory devices for storing data, logic devices for processing data, and hybrid devices capable of performing various functions simultaneously.

As advances in the electronics industry continue, demand for higher device integration may increase. This may cause several problems, such as reduced process margins in exposure processes for patterning fine patterns. As such, it may become more difficult to fabricate integrated circuit devices. Accordingly, to satisfy demand for high integration and high speed operation, various research is being conducted.

### SUMMARY

An object of the inventive concept is to provide a photolithography method including an initiated chemical vapor deposition (iCVD) process.

An object of the inventive concept is to provide a method of manufacturing a semiconductor device with improved reliability.

A photolithography method according to some embodiments of the inventive concept may include forming a photoresist pattern on a substrate and conformally forming a liner layer on the photoresist pattern, the forming of the liner layer may include a deposition process of reacting an initiator and a monomer with each other, the monomer may include multiple bonds between carbon atoms, the initiator may include a material that forms a radical by thermal decomposition, a copolymer may be formed by an initiating reaction between the radical and the monomer, and the liner layer may include the copolymer.

A photolithography method according to some embodiments of the inventive concept may include forming a photoresist pattern on a substrate, heating the substrate, conformally forming a liner layer on the substrate and the photoresist pattern, etching back the liner layer and the photoresist pattern to remove a portion of the liner layer and a portion of the photoresist pattern, performing a patterning process using the liner layer and the photoresist pattern as a mask, and removing the liner layer and the photoresist pattern by performing an etching process, the forming of the liner layer may include a deposition process of reacting an initiator and a monomer with each other, the monomer may include multiple bonds between carbon atoms, the initiator may include a material that forms a radical by thermal decomposition, a copolymer may be formed by an initiating reaction between the radical and the monomer, and the liner layer may include the copolymer.

A method of manufacture a semiconductor device according to some embodiments of the inventive concept may include forming a stacked pattern on a substrate, the stacked pattern including active layers and sacrificial layers alternately stacked with each other, forming a mask pattern on the substrate, heating the substrate to form a liner layer covering the substrate and the mask pattern, etching back the liner layer and the mask pattern to remove a portion of the liner layer and a portion of the mask pattern, performing a patterning process using the liner layer and the mask pattern as a mask to form a trench in the substrate, the trench defining an active pattern, and removing the liner layer and the mask pattern, the forming of the liner layer may include a deposition process of reacting an initiator and a monomer with each other, the monomer may include multiple bonds between carbon atoms, the initiator may include a material that forms a radical by thermal decomposition, a copolymer may be formed by an initiating reaction between the radical and the monomer, and the liner layer may include the copolymer.

### BRIEF DESCRIPTION OF DRAWINGS

Example embodiments will be more clearly understood from the following brief description taken in conjunction with the accompanying drawings. The accompanying drawings represent non-limiting, example embodiments as described herein.

FIGS. 1 to 5 are cross-sectional views illustrating a photolithography method according to some embodiments of the inventive concept.

FIG. 6 is a plan view illustrating a semiconductor device according to some embodiments of the inventive concept.

FIGS. 7A to 7D are cross-sectional views taken along lines A-A′, B-B′, C-C′, and D-D′ of FIG. 6, respectively.

FIGS. 8A, 8B, 9A, 9B, 10A, 10B, 10C, 10D, 11A, 11B, 11C, 11D, 12A, 12B, 12C, 12D, 13A, 13B, 13C, 13D, 14A, 14B, 14C and 14D are cross-sectional views illustrating a method of manufacturing a semiconductor device according to some embodiments of the inventive concept.

FIGS. 15A to 15E are cross-sectional views illustrating a method of forming active patterns according to some embodiments of the inventive concept.

FIGS. 16A to 16F are cross-sectional views illustrating a method of forming the structure shown in FIG. 14D according to some other embodiments of the inventive concept.

### DETAILED DESCRIPTION

Unless otherwise defined in chemical formulas of this specification, when a chemical bond is not drawn at a position where a chemical bond is to be drawn, it may mean that a hydrogen atom is bonded to the position.

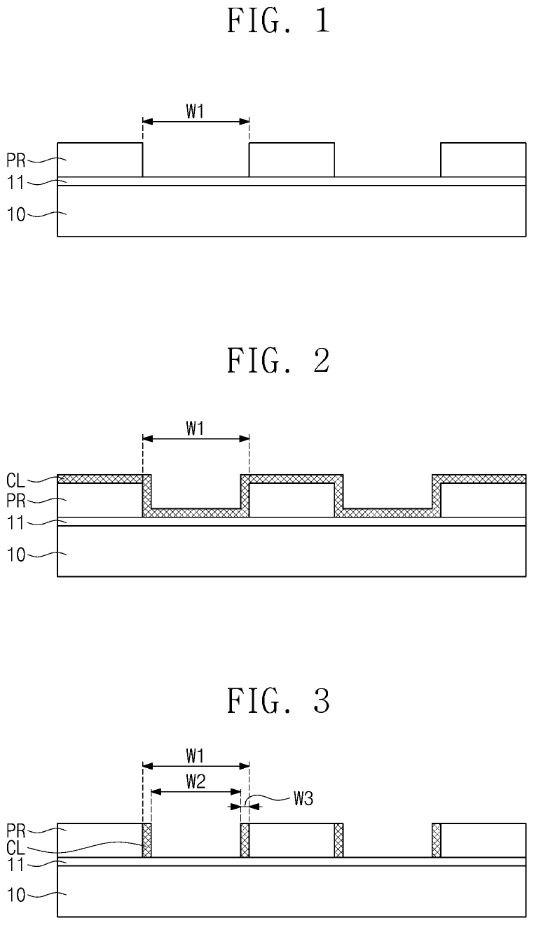

FIGS. 1 to 5 are cross-sectional views illustrating a photolithography method according to some embodiments of the inventive concept.

Referring to FIG. 1, a substrate 10 may be provided. The substrate 10 is not particularly limited, but may be a semiconductor wafer such as a silicon wafer. A photoresist pattern PR may be formed on the substrate 10. A stacked pattern 11 may be formed between the substrate 10 and the photoresist pattern PR. The stacked pattern 11 may be omitted. Although not shown, at least one or more layers may be further provided between the substrate 10 and the photoresist pattern PR.

The photoresist pattern PR may be the plural. A pair of photoresist patterns PR adjacent to each other may be spaced apart from each other by a certain distance. The distance between the pair of photoresist patterns PR may have a first width W1. The photoresist pattern PR may include a material different from that of the substrate 10. For example, the photoresist pattern PR may not include silicon (Si) and metal elements.

Referring to FIG. 2, a liner layer CL may be conformally formed on the substrate 10 and the photoresist pattern PR. The liner layer CL may extend on (e.g., cover) an upper surface and both sidewalls (e.g., opposing sidewalls) of the photoresist pattern PR. The liner layer CL may cover an upper surface of the substrate. In some embodiments, the liner layer CL may have a uniform thickness along a surface on which the liner layer CL is formed.

Forming the liner layer CL may include a deposition process of reacting an initiator and a monomer with each other. In detail, forming the liner layer CL may include an initiated chemical vapor deposition (iCVD) process.

An initiator may include a compound of Formula 1 below.

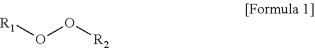

R1 and R2 are each independently an alkyl group having 1 to 5 carbon atoms, an alkynyl group having 2 to 15 carbon atoms, or a substituted or unsubstituted carbonyl group. In detail, the initiator may include at least one of tert-butyl peroxide (TBPO), tert-amylperoxide, tert-butykperoxybenzoate, and perfluorooctanesulfonyl fluoride. In some embodiments, the initiator may include tert-butyl peroxide (TBPO), tert-amylperoxide, tert-butykperoxybenzoate and/or perfluorooctanesulfonyl fluoride.

A monomer may include at least one multiple bond. The monomer may include double or triple bonds between carbons. The monomer may include a material capable of undergoing a polymer polymerization reaction by receiving a radical. The monomer may include a compound of Formula 2 below.

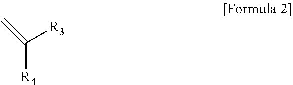

R3 and R4 are each independently hydrogen, an alkyl group having 1 to 15 carbon atoms, an alkynyl group having 1 to 15 carbon atoms, an aryl group having 1 to 15 carbon atoms, a substituted or unsubstituted carboxy group, a substituted or unsubstituted carbonyl group, or a substituted or an unsubstituted alkoxy group.

In detail, the monomer includes at least one of divinylbenzene (DVB), cyclohexyl methacrylate, glycidyl methacrylate (GMA), hydroxyethyl methacrylate, 2-hydroxyethyl acrylate (HEA), methacrylic anhydride, ethylene glycol dimethacrylate, 1,3-butanediol diacrylate, 1,3,5,7-tetravinyl-1,3,5,7-tetramethyl, vinylimidazole, acrylic acid, N-vinyl-2-pyrrolidone, and 1H, 1H,2H,2H-perfluorodecyl methacrylate. In some embodiments, the monomer may include divinylbenzene (DVB), cyclohexyl methacrylate, glycidyl methacrylate (GMA), hydroxyethyl methacrylate, 2-hydroxyethyl acrylate (HEA), methacrylic anhydride, ethylene glycol dimethacrylate, 1,3-butanediol diacrylate, 1,3,5,7-tetravinyl-1,3,5,7-tetramethyl, vinylimidazole, acrylic acid, N-vinyl-2-pyrrolidone and/or 1H, 1H,2H,2H-perfluorodecyl methacrylate.

A method of forming the liner layer CL will be described in detail with reference to Chemical equations 1 to 4 below.

To form the liner layer CL, the initiator and the monomer may be provided on the substrate 10 in a gaseous state. In this case, the monomer may be provided more than the initiator. A flow rate of the monomer may be 2 to 3 times a flow rate of the initiator. The monomer may include multiple bonds between carbon atoms. The initiator may include a material that forms a radical by thermal decomposition.

Referring to Chemical Equation 1 below, the initiator may be decomposed by heat to form the radical. The radical may be an oxygen radical. To this end, a movement path of the initiator may be heated. The initiator may be supplied through a mixing block and a gas line supplying the initiator to the mixing block. The mixing block may include a showerhead and a block plate. The showerhead, the block plate and gas line may be heated using a filament or heater. A heating temperature may be 100° C. to 300° C. Applying heat to the initiator may not include a plasma process. As the plasma process is not used, deformation of the photoresist pattern PR may be reduced or prevented.

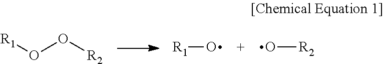

Referring to Chemical Equation 2 below, the radical formed from the initiator may react with multiple bonds of the monomer on the substrate 10. For the reaction of the radical, the substrate 10 may be heated to a temperature of 30° C. to 250° C. Due to the reaction of the radical, a monomer including a new radical may be formed.

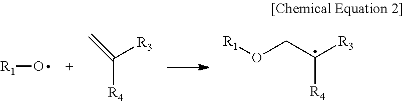

Referring to Chemical Equation 3 below, the radical of the monomer may react with multiple bonds of another monomer. The reaction of the radical may occur in a chain. The monomers may form a polymer due to a chain radical reaction. A length of the chain of monomers may be increased by the chain radical reaction. The liner layer CL may include the polymer.

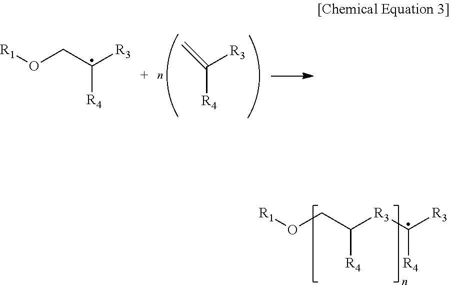

Referring to Chemical Equation 4 below, the chain reaction of the radical may be stopped. The reaction of the radical may be stopped by combining the radical of the two growing monomer chains. Alternatively, the radical may react with an impurity and the reaction of the radical may be stopped.

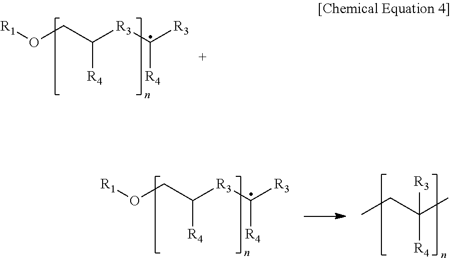

When forming the liner layer CL, a partial pressure of the monomer relative to a saturation pressure of the monomer may be in a range of from 0.01 to 0.2. In some embodiments, (the partial pressure of the monomer)/(the saturation pressure of the monomer) may be in a range of from 0.01 to 0.2. The saturation pressure may be a saturation pressure of the monomer at a temperature of the substrate. When the partial pressure of the monomer exceeds 0.2, the liner layer CL may not be conformally formed on the substrate but may fill a gap to form a gapfill.

The liner layer CL may include carbon (C), hydrogen (H), and oxygen (O). A content of carbon (C), hydrogen (H), and oxygen (O) in the liner layer CL may be 80 at % to 100 at %. The liner layer CL may be an organic layer. The liner layer CL may not include inorganic materials such as silicon (Si) and a metal element. By performing the initiated chemical vapor deposition process (iCVD), it is possible to reduce or prevent damage on the substrate 10 by a plasma process.

Referring to FIG. 3, after forming the liner layer CL, the liner layer CL and the photoresist pattern PR may be etched back. A portion of the liner layer CL and a portion (e.g., an upper portion) of the photoresist pattern PR may be removed. The portion of the liner layer CL covering the upper surface of the photoresist pattern PR may be removed. The portion of the liner layer CL directly covering the upper surface of the substrate 10 may be removed. In some embodiments, horizontal portions of the liner layer CL may be removed such that vertical portions (portions formed on the sidewalls of the photoresist pattern PR) of the liner layer CL may remain, as illustrated in FIG. 3.

On the other hand, the liner layer CL covering the sidewalls of the photoresist pattern PR may not be removed. Accordingly, a distance between the pair of adjacent photoresist patterns PR may decrease from the first width W1 to a second width W2. The second width W2 may be smaller than the first width W1. This may be due to a thickness W3 of the liner layer CL that is not removed. The second width W2 may be a width of a space between the adjacent vertical portions of the liner layer CL, as illustrated in FIG. 3.

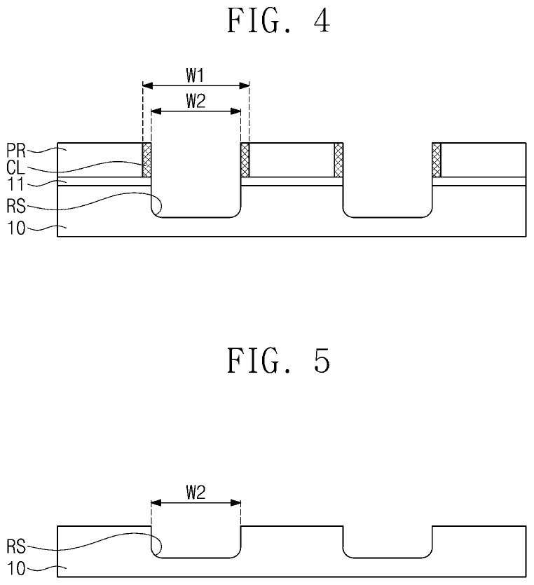

Referring to FIG. 4, a patterning process may be performed using the liner layer CL and the photoresist pattern PR as an etching mask. The substrate 10 and the stacked pattern 11 may be etched by the patterning process to form a recess RS. A width of the recess RS may be equal to the second width W2. The width of the recess RS may be adjusted by adjusting the thickness W3 of the liner layer CL.

Referring to FIG. 5, the liner layer CL and the photoresist pattern PR may be removed. The liner layer CL and the photoresist pattern PR may be removed (e.g., simultaneously removed) by a single etching process. To this end, in the etching process, an etching ratio of the liner layer CL to the photoresist pattern PR may be the same or similar. In some embodiments, the etching ratio of the liner layer CL to the photoresist pattern PR may be the same. In detail, in the etching process, the etching ratio of the liner layer CL to the photoresist pattern PR may be in a range of from 0.8 to 1.2. The etching process may be a dry etching process. As used herein, an etching ratio of a layer A to a layer B means a ratio of etch rates between the layer A and the layer B (i.e., etch selectivity), and that ratio of etch rates is calculated as (etch rate of the layer A)/(etch rate of the layer B).

In some embodiments of the inventive concept, the polymer constituting the photoresist pattern PR may include one monomer. In some other embodiments of the inventive concept, a plurality of monomers may be used to form the liner layer CL having the same or similar etching rate as the photoresist pattern PR. For example, a copolymer constituting the liner layer CL may include a first monomer and a second monomer. The second monomer may be different from the first monomer. In some embodiments, multiple monomer species are used to form the liner layer CL. An etching rate of the first monomer may be smaller than an etching rate of the photoresist pattern PR, and an etching rate of the second monomer may be larger than the etching rate of the photoresist pattern PR. The liner layer CL having the same or similar etching rate as that of the photoresist pattern PR may be provided by adjusting the etching rates of the first monomer and the second monomer.

For example, the first monomer may be divinylbenzene (DVB), and the second monomer may be 2-hydroxyethyl acrylate (HEA) or glycidyl methacrylate (GMA). The initiator may be tert-butyl peroxide (TBPO). In this case, the etching rate of the first monomer may be smaller than that of the photoresist pattern PR, and the etching rate of the second monomer may be greater than that of the photoresist pattern PR. The initiator and the first and second monomers may form a copolymer through the aforementioned radical reaction. The copolymer may have the same or similar etching rate as the photoresist pattern PR. In some embodiments, the copolymer may have the same etching rate as the photoresist pattern PR.

According to some embodiments of the inventive concept, the liner layer CL may be formed using the initiated chemical vapor deposition process (iCVD). As the liner layer CL has the etching rate similar to that of the photoresist pattern PR, the liner layer CL and the photoresist pattern PR may be removed by the single etching process. Thus, it is possible to reduce or prevent additional etching of the substrate 10. An increase in the width W2 of the etched substrate may be reduced or prevented. As a result, precision and accuracy of the photolithography process may be improved.

### Experimental Example

In the photolithography method of the inventive concept, tert-butyl peroxide (TBPO) was used as an initiator. Divinylbenzene (DVB) was used as a monomer. Polydivinylbenzene (pDVB) was formed by the following Chemical Equation 5 using the initiator and monomer.

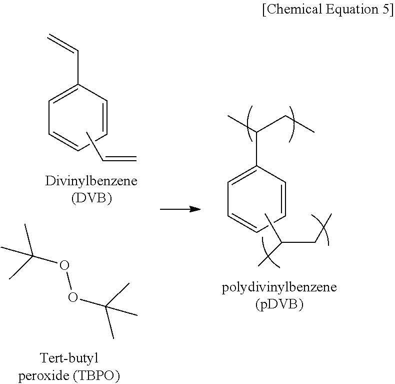

A temperature of the filament was 130° C. A flow rate of the monomer (DVB) was adjusted to 2 sccm to 3 sccm. A process pressure was adjusted to 100 mTorr to 300 mTorr. A temperature of a substrate was adjusted to 30° C. to 70° C. A polymer was deposited on the substrate 10 by reacting the initiator and the monomer in a gaseous state. By varying deposition process conditions, it was confirmed whether the liner layer CL was conformally formed on the substrate 10 and the photoresist patterns PR. Specific conditions were shown in Table 1 below.

TABLE 1

| | Flow rate | Flow rate | Filament | Process | Substrate | |
|---|---|---|---|---|---|---|
| Experimental | of DVB | of TBPO | Temp | Pressure | Temp | |
| Condition | (sccm) | (sccm) | (° C.) | (mTorr) | (° C.) | Pm/Psat |
| Example 1 | 3 | 1 | 130 | 200 | 50 | 0.153 |
| Example 2 | 2 | 1 | 130 | 200 | 70 | 0.060 |
| Example 3 | 2 | 1 | 130 | 100 | 50 | 0.077 |
| Comparative | 3 | 1 | 130 | 200 | 30 | 0.440 |
| Example 1 | | | | | | |
| Comparative | 3 | 1 | 130 | 300 | 50 | 0.230 |
| Example 2 | | | | | | |

Table 1 shows various iCVD deposition conditions for polymers. As a result of the experiment, in Examples 1, 2, and 3, the liner layer CL was conformally formed on the substrate 10 and the photoresist pattern PR. In Examples 2 and 3, the thickness of the liner layer CL was formed more uniformly than in Example 1. On the other hand, in Comparative Examples 1 and 2, the patterning process could not be performed using the photoresist pattern PR as a mask because a gap fill was formed. That is, in Comparative Examples 1 and 2, the liner layer was not conformally deposited on the substrate. Through the above experimental example, it may be seen that the partial pressure of the monomer (Pm) with respect to the saturation pressure of the monomer (Psat) is preferably in a range of from 0.01 to 0.2. In some embodiments, (partial pressure of the monomer)/(saturation pressure of the monomer) is in a range of from 0.01 to 0.2.

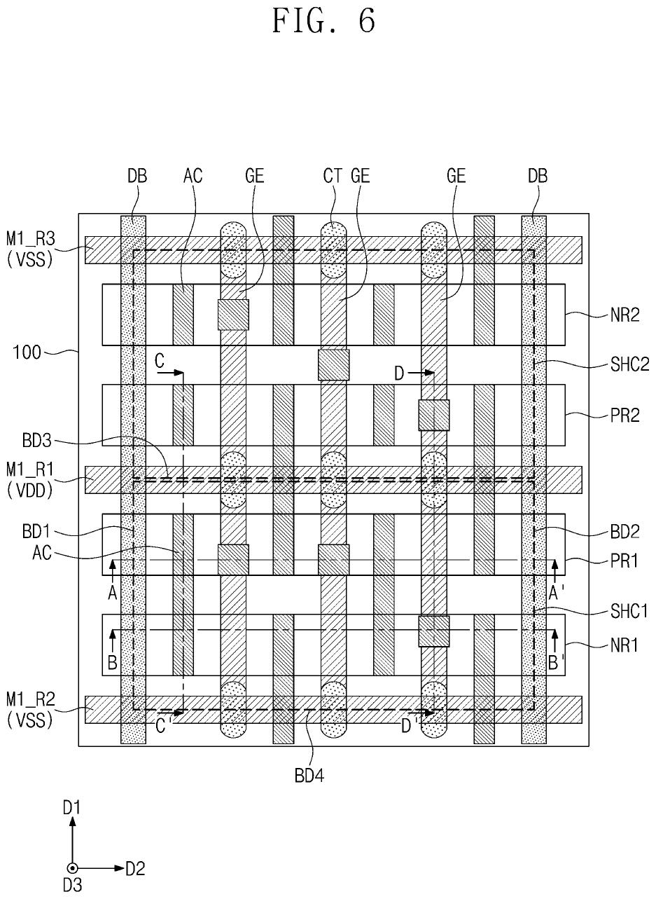

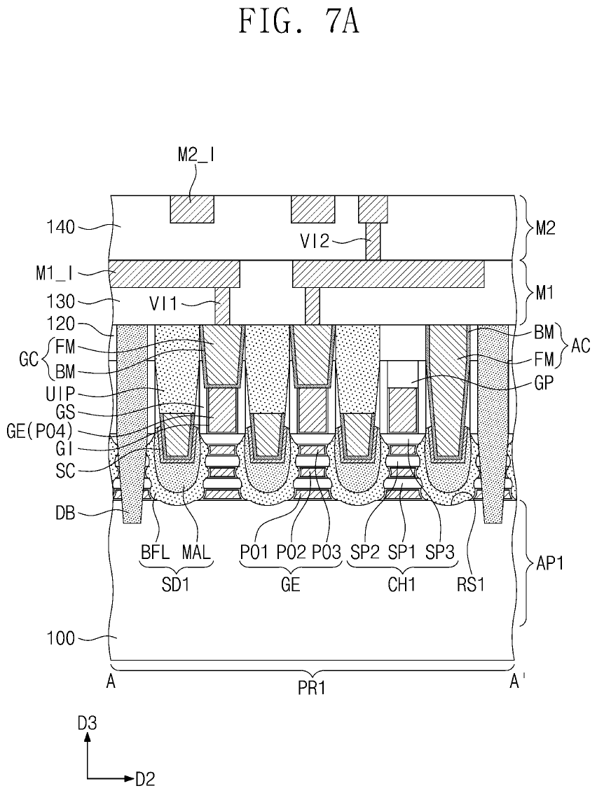

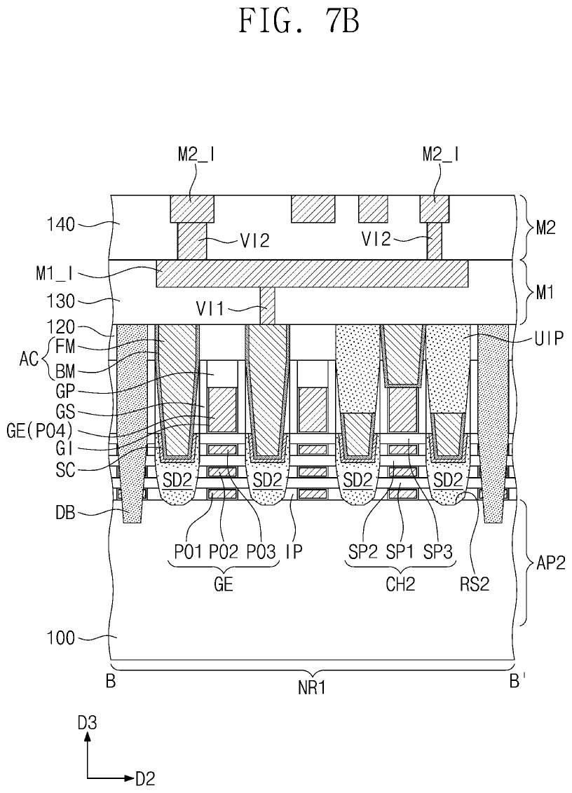

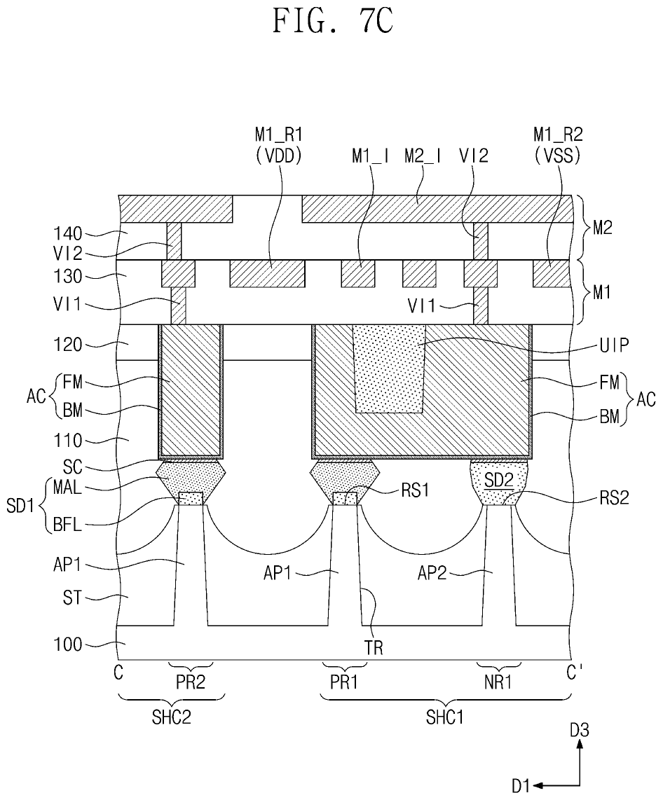

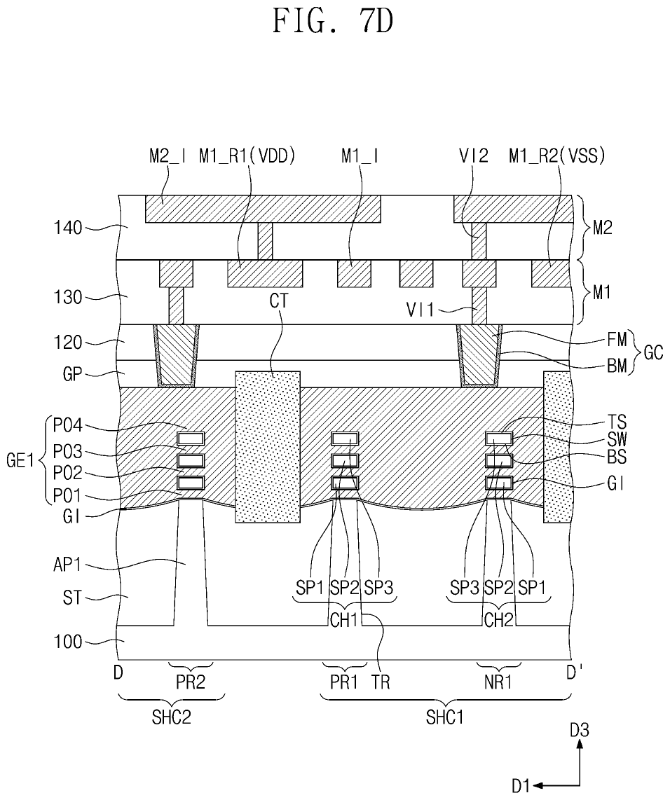

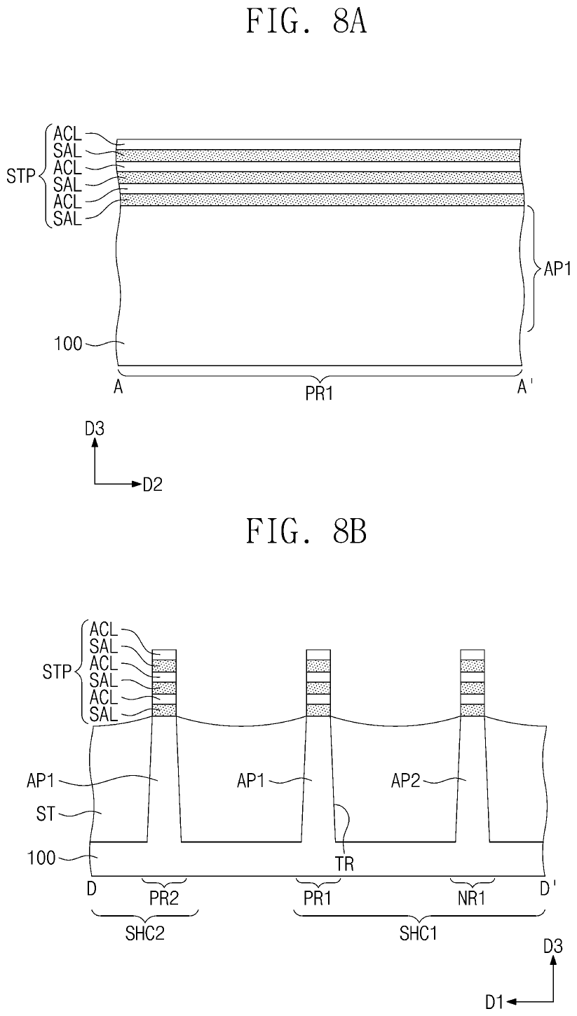

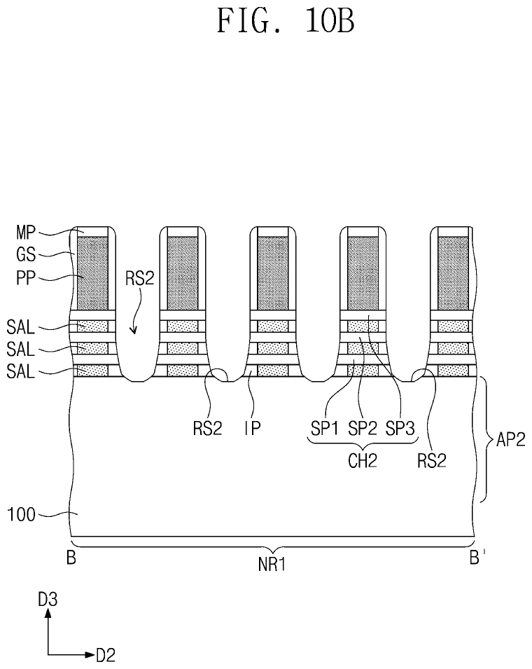

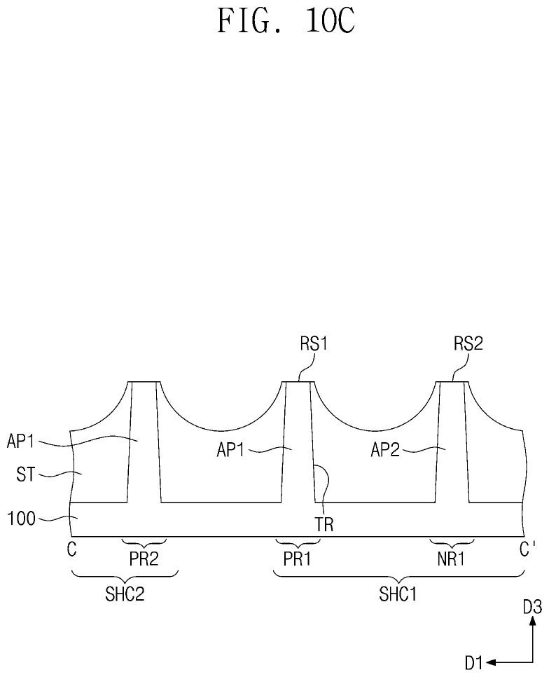

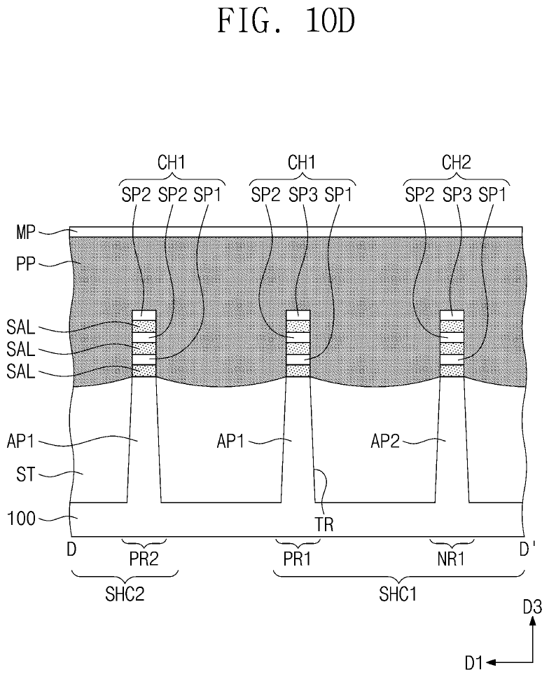

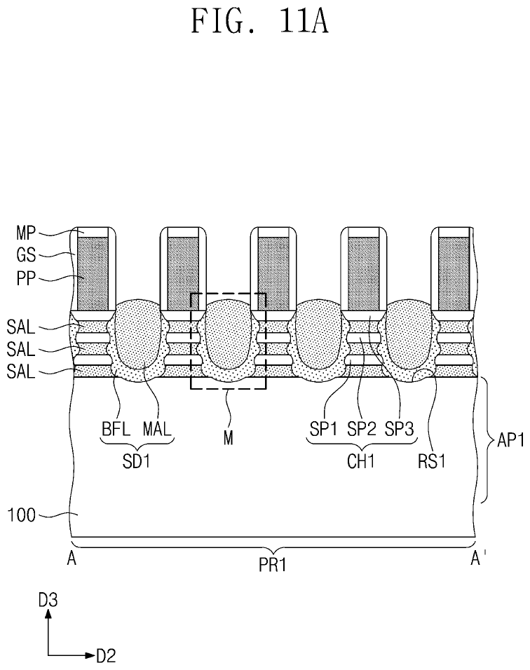

FIG. 6 is a plan view illustrating a semiconductor device according to some embodiments of the inventive concept. FIGS. 7A to 7D are cross-sectional views taken along lines A-A′, B-B′, C-C′, and D-D′ of FIG. 6, respectively. FIGS. 8A to 14D are cross-sectional views illustrating a method of manufacturing a semiconductor device according to some embodiments of the inventive concept. FIGS. 8A, 9A, 10A, 11A, 12A, 13A, and 14A are cross-sectional views taken along line A-A′. FIGS. 10B, 11B, 12B, 13B, and 14B are cross-sectional views taken along line B-B′. FIGS. 10C, 11C, 12C, 13C, and 14C are cross-sectional views taken along line C-C′. FIGS. 8B, 9B, 10D, 11D, 12D, 13D, and 14D are cross-sectional views taken along line D-D′.

Referring to FIGS. 6, 8A and 8B, a substrate 100 including first and second PMOSFET regions PR1 and PR2 and first and second NMOSFET regions NR1 and NR2 may be provided. Active layers ACL and sacrificial layers SAL may be alternately stacked on the substrate 100. The active layers ACL may include one of silicon (Si), germanium (Ge), and silicon-germanium (SiGe), and the sacrificial layers SAL may include another one of silicon (Si), germanium (Ge), and silicon-germanium (SiGe).

The sacrificial layer SAL may include a material having an etch selectivity with respect to the active layer ACL. For example, the active layers ACL may include silicon (Si), and the sacrificial layers SAL may include silicon-germanium (SiGe). A concentration of germanium (Ge) in each of the sacrificial layers SAL may be 10 at % to 30 at %.

Mask patterns may be formed on the first and second PMOSFET regions PR1 and PR2 and the first and second NMOSFET regions NR1 and NR2 of the substrate 100, respectively. A patterning process may be performed using the mask patterns as an etch mask to form a trench TR defining first and second active patterns AP1 and AP2. A detailed description of the patterning process will be described later. The first active pattern AP1 may be formed on each of the first and second PMOSFET regions PR1 and PR2. The second active pattern AP2 may be formed on each of the first and second NMOSFET regions NR1 and NR2.

A stacked pattern STP may be formed on each of the first and second active patterns AP1 and AP2. The stacked pattern STP may include active layers ACL and sacrificial layers SAL that are alternately stacked with each other. The stacked pattern STP may be formed together with the first and second active patterns AP1 and AP2 during the patterning process.

A device isolation layer ST may be formed to fill the trench TR. In detail, an insulating layer may be formed on the entire surface of the substrate 100 to cover the first and second active patterns AP1 and AP2 and the stacked patterns STP. The insulating layer may be recessed until the stacked patterns STP are exposed, to form the device isolation layer ST.

The device isolation layer ST may include an insulating material such as a silicon oxide layer. The stacked patterns STP may be exposed on the device isolation layer ST. In other words, the stacked patterns STP may vertically protrude from the device isolation layer ST.

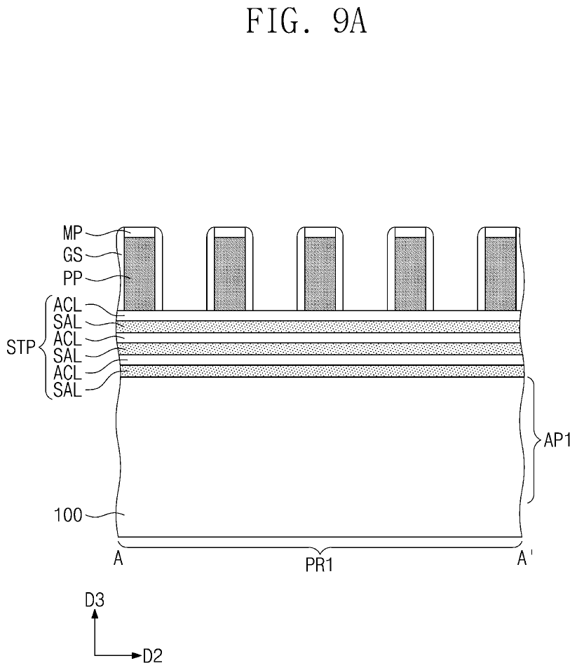

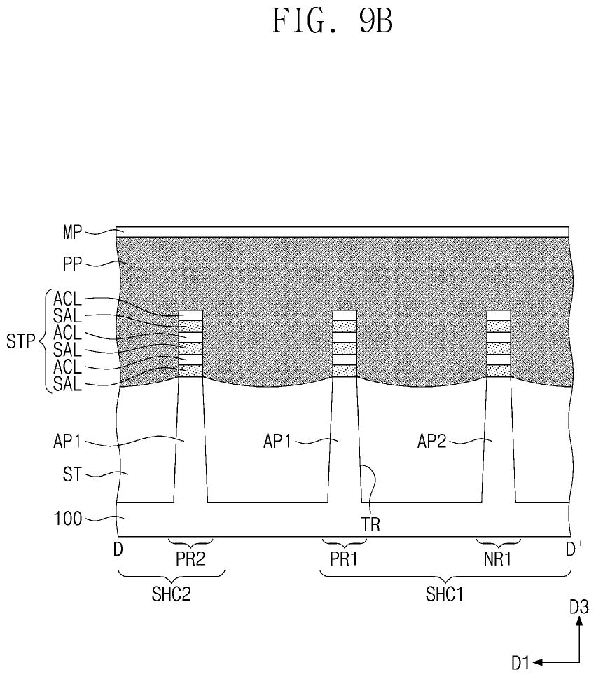

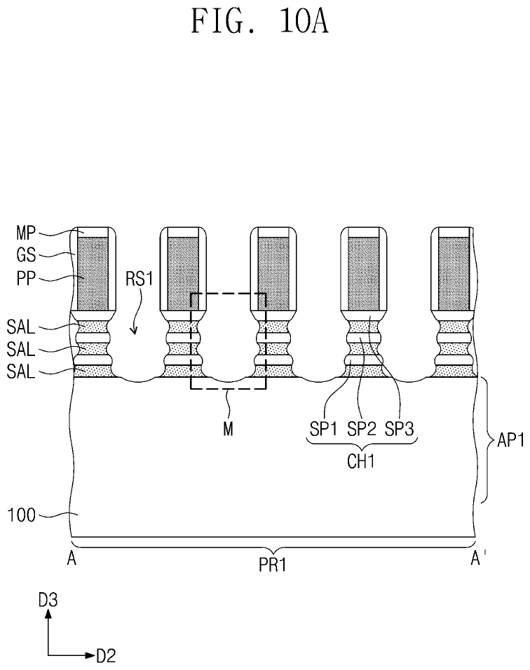

Referring to FIGS. 9A and 9B, sacrificial patterns PP crossing the stacked patterns STP may be formed on the substrate 100. Each of the sacrificial patterns PP may be formed in a line shape or bar shape extending in a first direction D1. The sacrificial patterns PP may be arranged in a second direction D2 with a first pitch.

In detail, forming the sacrificial patterns PP may include forming a sacrificial layer on the entire surface of the substrate 100, forming hard mask patterns MP on the sacrificial layer, and patterning the sacrificial layer using the hard mask patterns MP as an etch mask. The sacrificial layer may include polysilicon.

A pair of gate spacers GS may be formed on both sidewalls of each of the sacrificial patterns PP. Forming the gate spacers GS may include conformally forming a gate spacer layer on the entire surface of the substrate 100 and anisotropically etching the gate spacer layer. As described herein with reference to FIG. 6, the gate spacer GS may be a multi-layer including a first spacer GS1 and a second spacer GS2.

Referring to FIGS. 10A to 10D, first recesses RS1 may be formed in the stacked pattern STP on the first active pattern AP1. Second recesses RS2 may be formed in the stacked pattern STP on the second active pattern AP2. While forming the first and second recesses RS1 and RS2, the device isolation layer ST on both sides of each of the first and second active patterns AP1 and AP2 may be further recessed (refer to FIG. 10C).

In detail, the first recesses RS1 may be formed by etching the stacked pattern STP on the first active pattern AP1 using the hard mask patterns MP and the gate spacers GS as an etch mask. The first recess RS1 may be formed between the pair of sacrificial patterns PP. Forming the first recess RS1 may include additionally performing a selective etching process on the exposed sacrificial layers SAL. Accordingly, the first recess RS1 may have a wavy inner wall.

The second recesses RS2 in the stacked pattern STP on the second active pattern AP2 may be formed in the same manner as forming the first recesses RS1. However, forming the second recess RS2 may further include forming inner spacers IP in a region where the sacrificial layer SAL is recessed. As a result, an inner wall of the second recess RS2 may not have a wavy shape like the inner wall of the first recess RS1.

From the active layers ACL, first to third semiconductor patterns SP1, SP2, and SP3 sequentially stacked between adjacent first recesses RS1 may be formed, respectively. From the active layers ACL, first to third semiconductor patterns SP1, SP2, and SP3 sequentially stacked between adjacent second recesses RS2 may be formed, respectively. The first to third semiconductor patterns SP1, SP2, and SP3 between the adjacent first recesses RS1 may constitute a first channel pattern CH1. The first to third semiconductor patterns SP1, SP2, and SP3 between adjacent second recesses RS2 may constitute a second channel pattern CH2.

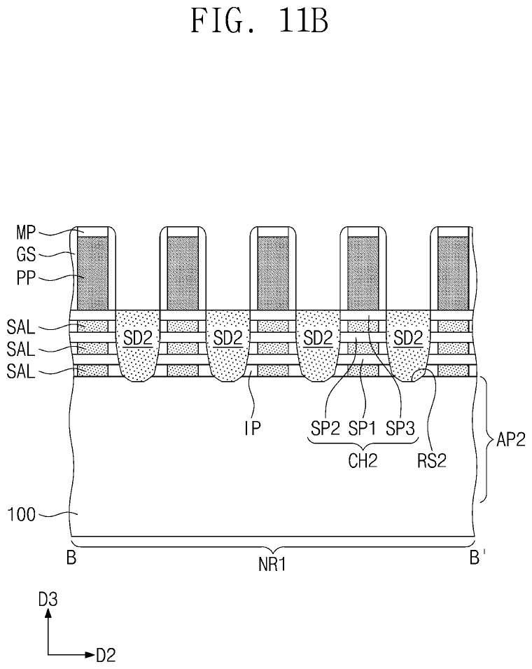

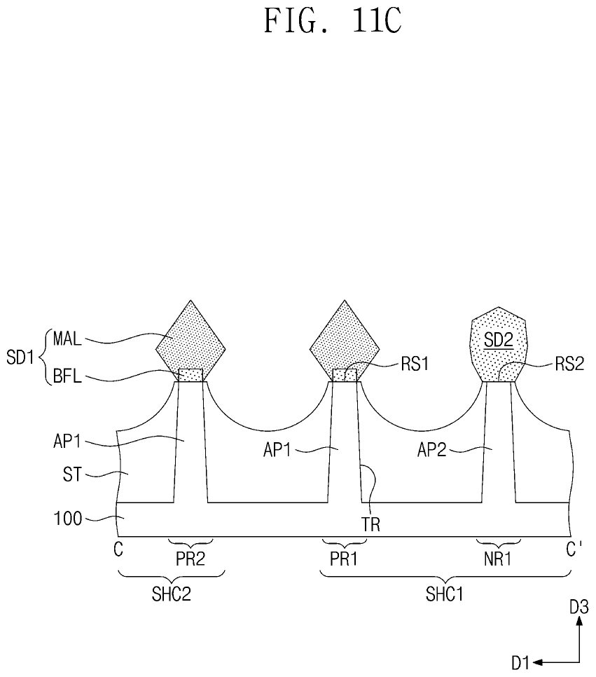

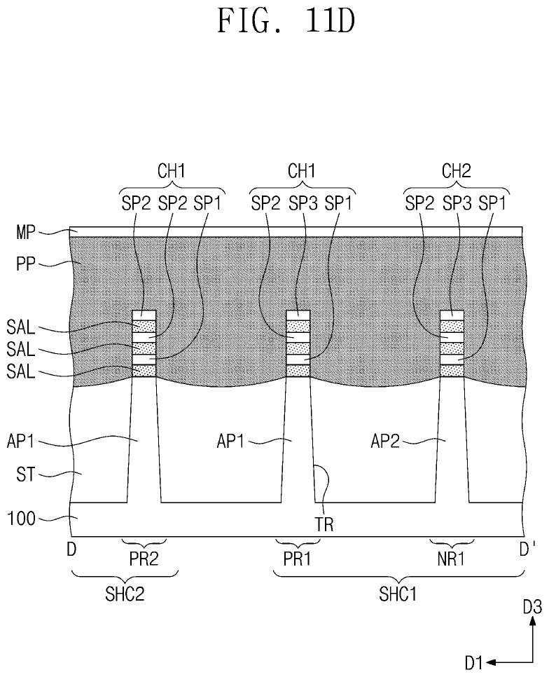

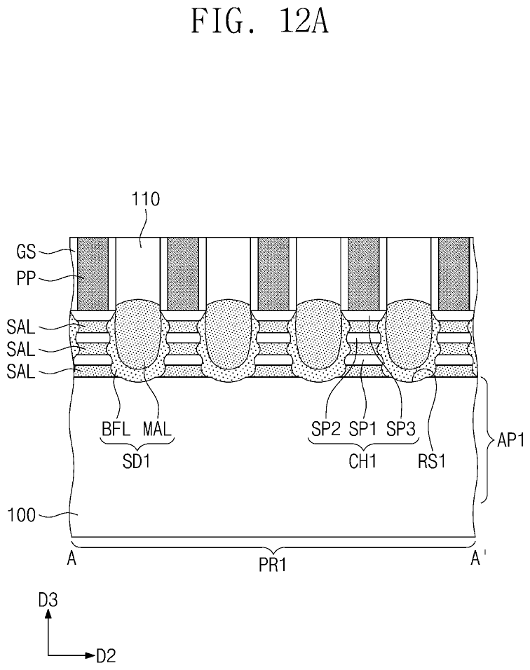

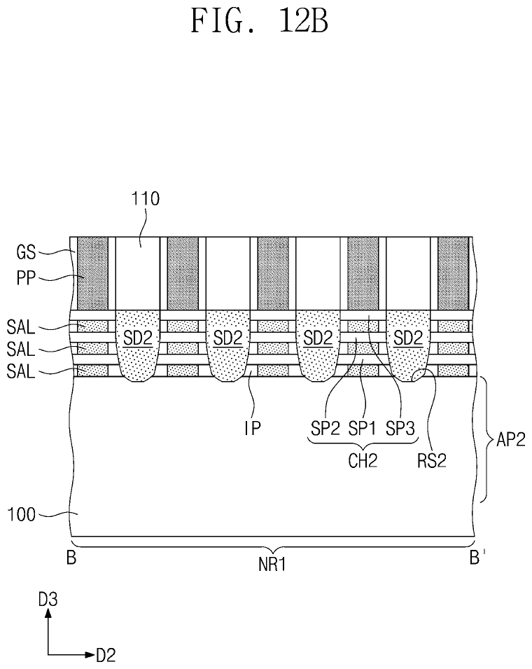

Referring to FIGS. 11A to 11D, first source/drain patterns SD1 may be formed in the first recesses RS1, respectively. In detail, the buffer layer BFL may be formed by performing an SEG process using the inner wall of the first recess RS1 as a seed layer. The buffer layer BFL may be grown using the substrate 100 and the first to third semiconductor patterns SP1, SP2, and SP3 exposed by the first recess RS1 as seeds. For example, the SEG process may include a chemical vapor deposition (CVD) process or a molecular beam epitaxy (MBE) process.

The buffer layer BFL may include a semiconductor element (e.g., SiGe) having a greater lattice constant than a lattice constant of a semiconductor element of the substrate 100. The buffer layer BFL may include germanium (Ge) at a relatively low concentration. In some other embodiments of the inventive concept, the buffer layer BFL may include only silicon (Si) excluding germanium (Ge). A concentration of germanium (Ge) in the buffer layer BFL may be 0 at % to 10 at %.

A main layer MAL may be formed by performing a SEG process on the buffer layer BFL. The main layer MAL may be formed to completely fill the first recess RS1. The main layer MAL may include germanium (Ge) at a relatively high concentration. For example, a concentration of germanium (Ge) in the main layer MAL may be 30 at % to 70 at %.

While forming the buffer layer BFL and the main layer MAL, an impurity (e.g., boron, gallium, or indium) that causes the first source/drain pattern SD1 to have a p-type may be injected in-situ. As another example, an impurity may be implanted into the first source/drain pattern SD1 after the first source/drain pattern SD1 is formed.

Second source/drain patterns SD2 may be formed in the second recesses RS2, respectively. In detail, the second source/drain pattern SD2 may be formed by performing a SEG process using the inner wall of the second recess RS2 as a seed layer. For example, the second source/drain pattern SD2 may include the same semiconductor element (e.g., Si) as the substrate 100.

While the second source/drain pattern SD2 is formed, an impurity (e.g., phosphorus, arsenic, or antimony) that causes the second source/drain pattern SD2 to have an n-type may be injected in-situ. In some embodiments, an impurity may be implanted into the second source/drain pattern SD2 after the second source/drain pattern SD2 is formed.

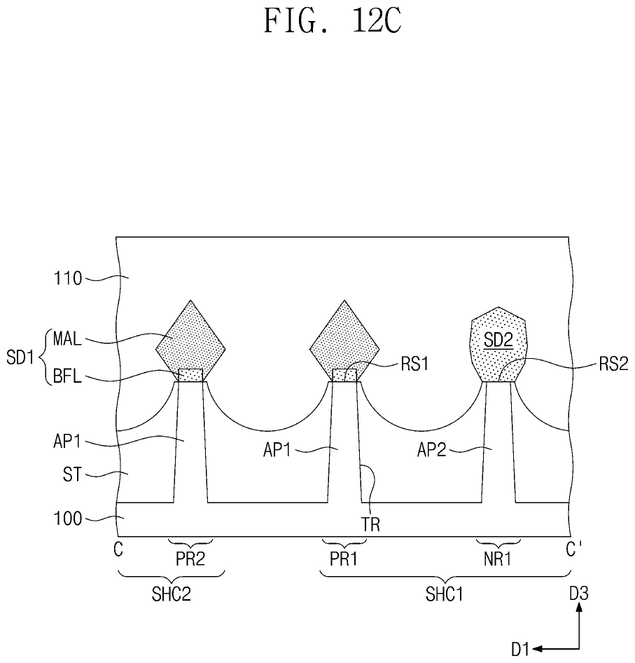

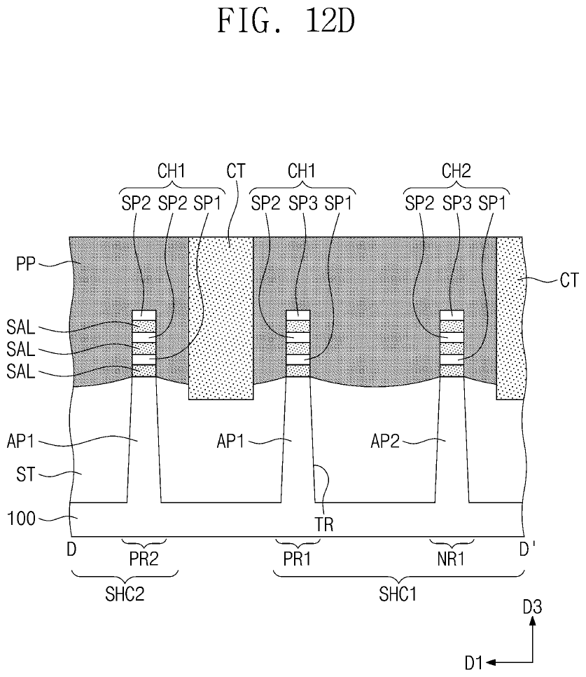

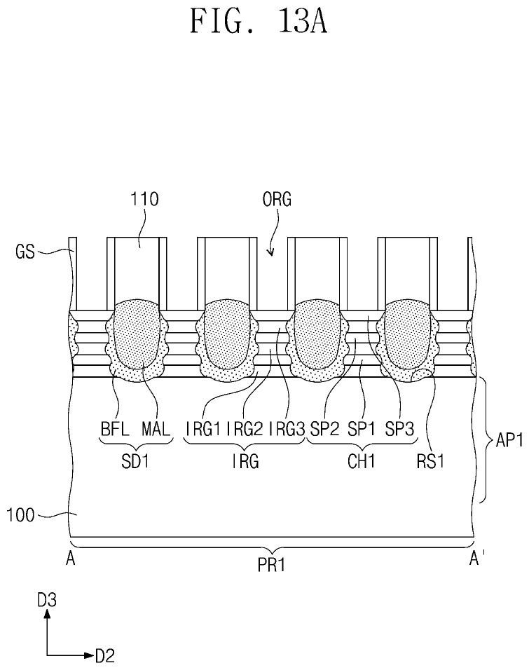

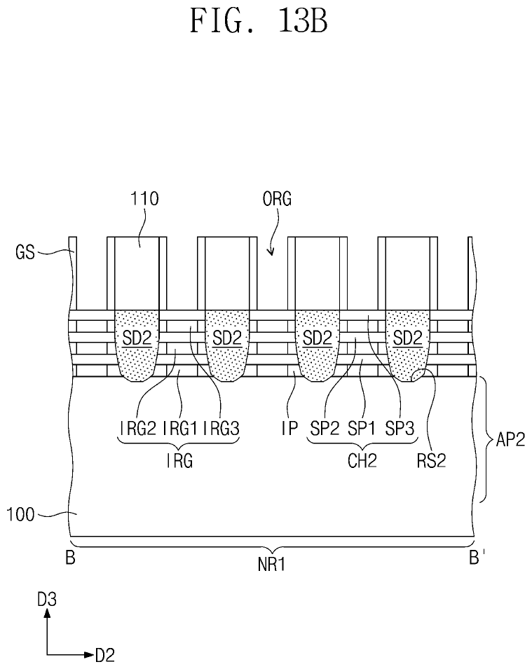

Referring to FIGS. 12A to 12D, a first interlayer insulating layer 110 covering the first and second source/drain patterns SD1 and SD2, the hard mask patterns MP, and the gate spacers GS may be formed. For example, the first interlayer insulating layer 110 may include a silicon oxide layer.

The first interlayer insulating layer 110 may be planarized until upper surfaces of the sacrificial patterns PP are exposed. Planarization of the first interlayer insulating layer 110 may be performed using an etch back or chemical mechanical polishing (CMP) process. During the planarization process, all of the hard mask patterns MP may be removed. As a result, the upper surface of the first interlayer insulating layer 110 may be coplanar with the upper surfaces of the sacrificial patterns PP and the upper surfaces of the gate spacers GS.

A region of the sacrificial pattern PP may be selectively opened using lithography. For example, the region of the sacrificial pattern PP on third and fourth boundaries BD3 and BD4 of a first single height cell SHC1 may be selectively opened. The region of the open sacrificial pattern PP may be selectively etched and removed. An insulating material may be filled in a space where the sacrificial pattern PP is removed to form a gate cutting pattern CT.

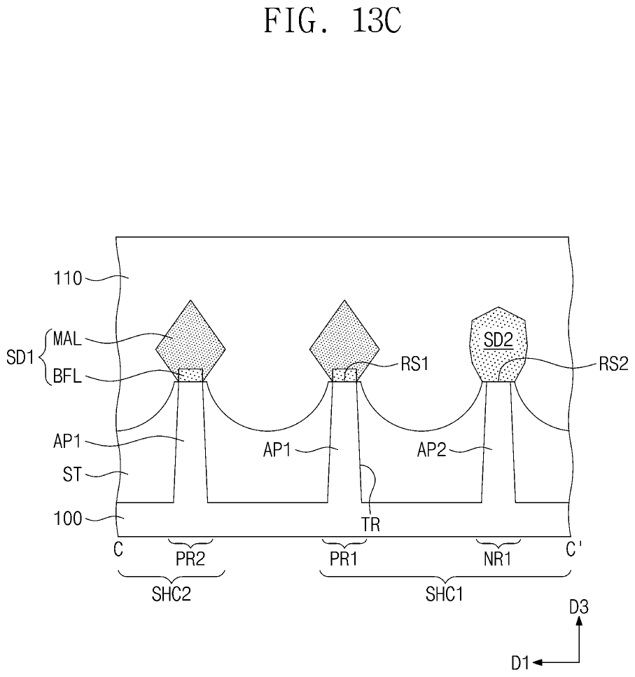

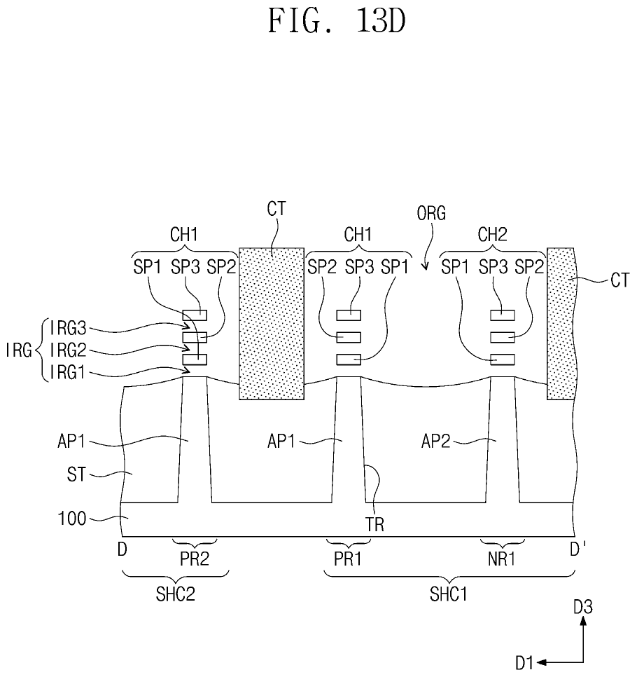

Referring to FIGS. 13A to 13D, the exposed sacrificial patterns PP may be selectively removed. By removing the sacrificial patterns PP, an outer region ORG exposing the first and second channel patterns CH1 and CH2 may be formed (refer to FIG. 13D). Removing the sacrificial patterns PP may include wet etching using an etchant that selectively etches the polysilicon.

The sacrificial layers SAL exposed through the outer region ORG may be selectively removed to form inner regions IRG (refer to FIG. 13D). In detail, an etching process for selectively etching the sacrificial layers SAL may be performed to remove only the sacrificial layers SAL while leaving the first to third semiconductor patterns SP1, SP2, and SP3 intact. The etching process may have a high etching rate for silicon-germanium having a relatively high germanium concentration. For example, the etching process may have a high etching rate for silicon-germanium having a germanium concentration greater than 10 at %.

During the etching process, the sacrificial layers SAL on the first and second PMOSFET regions PR1 and PR2 and the first and second NMOSFET regions NR1 and NR2 may be removed. The etching process may be wet etching. The etching material used in the etching process may quickly remove the sacrificial layer SAL having a relatively high germanium concentration. Meanwhile, the first source/drain pattern SD1 on the first and second PMOSFET regions PR1 and PR2 may be protected during the etching process due to the buffer layer BFL having a relatively low germanium concentration.

Referring to FIG. 13D, as the sacrificial layers SAL are selectively removed, the stacked first to third semiconductor patterns SP1, SP2, SP3 may remain on each of the first and second active patterns AP1 and AP2. First to third inner regions IRG1, IRG2, and IRG3 may be respectively formed through regions where the sacrificial layers SAL are removed.

In detail, the first inner region IRG1 may be formed between the active pattern AP1 or AP2 and the first semiconductor pattern SP1, the second inner region IRG1 may be formed between the first semiconductor pattern SP1 and the second semiconductor pattern SP2, and the third inner region IRG3 may be formed between the second semiconductor pattern SP2 and the third semiconductor pattern SP3.

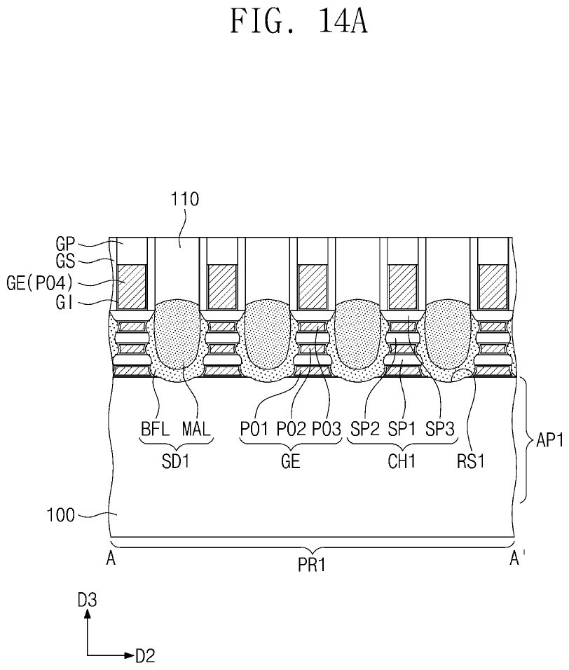

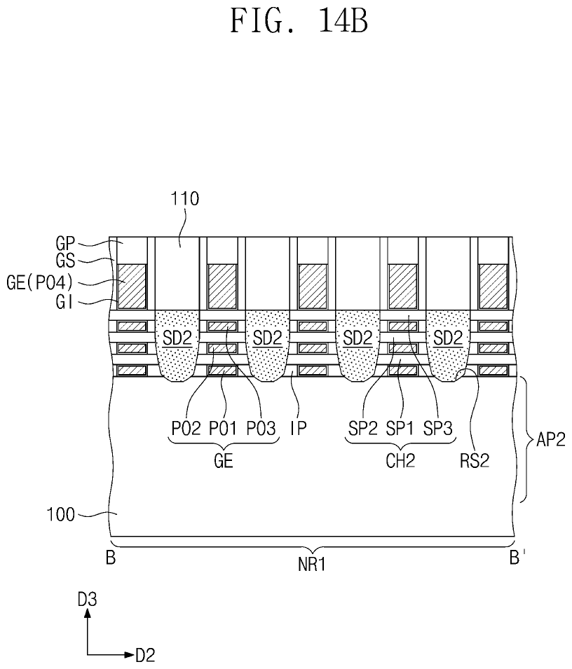

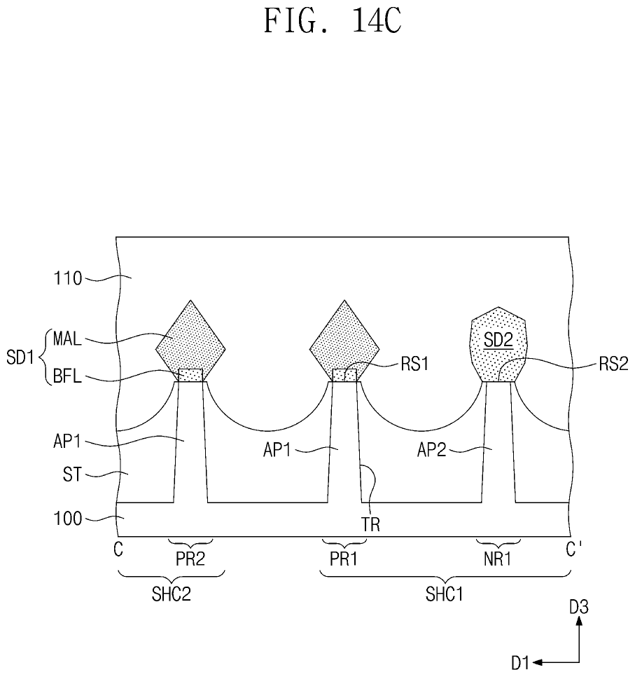

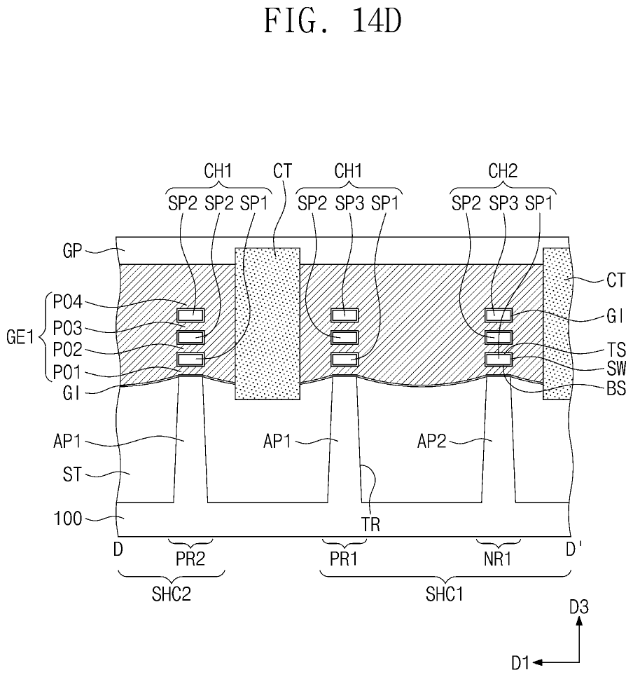

Referring to FIGS. 14A to 14D, a gate insulating layer GI may be conformally formed on the exposed first to third semiconductor patterns SP1, SP2, and SP3. A gate electrode GE may be formed on the gate insulating layer GI. The gate electrode GE may include first to third portions PO1, PO2, and PO3 respectively formed in the first to third inner regions IRG1, IRG2, and IRG3, and a fourth part PO4 formed in the outer region ORG.

As the gate electrode GE is recessed, a height thereof may be reduced. While the gate electrode GE is recessed, upper portions of the first and second gate cutting patterns CT1 and CT2 may also be slightly recessed. A gate capping pattern GP may be formed on the recessed gate electrode GE.

Referring to FIGS. 6 and 7A to 7D, a second interlayer insulating layer 120 may be formed on the first interlayer insulating layer 110. The second interlayer insulating layer 120 may include a silicon oxide layer. Active contacts AC electrically connected to the first and second source/drain patterns SD1 and SD2 may be formed through the second interlayer insulating layer 120 and the first interlayer insulating layer 110. A gate contact GC electrically connected to the gate electrode GE may be formed through the second interlayer insulating layer 120 and the gate capping pattern GP.

Forming each active contact AC and gate contact GC may include forming a barrier pattern BM and forming a conductive pattern FM on the barrier pattern BM. The barrier pattern BM may be conformally formed and may include a metal layer/metal nitride layer. The conductive pattern FM may include a low-resistance metal.

A pair of separation structures DB may be formed on both sides of each of the first and second single height cells SHC1 and SHC2. The separation structure DB may extend from the second insulating interlayer 120 into the active pattern AP1 or AP2 through the gate electrode GE. The separation structure DB may include an insulating material such as a silicon oxide layer or a silicon nitride layer.

A third interlayer insulating layer 130 may be formed on the active contacts AC and the gate contacts GC. A first metal layer M1 may be formed in the third interlayer insulating layer 130. A fourth interlayer insulating layer 140 may be formed on the third interlayer insulating layer 130. A second metal layer M2 may be formed in the fourth interlayer insulating layer 140.

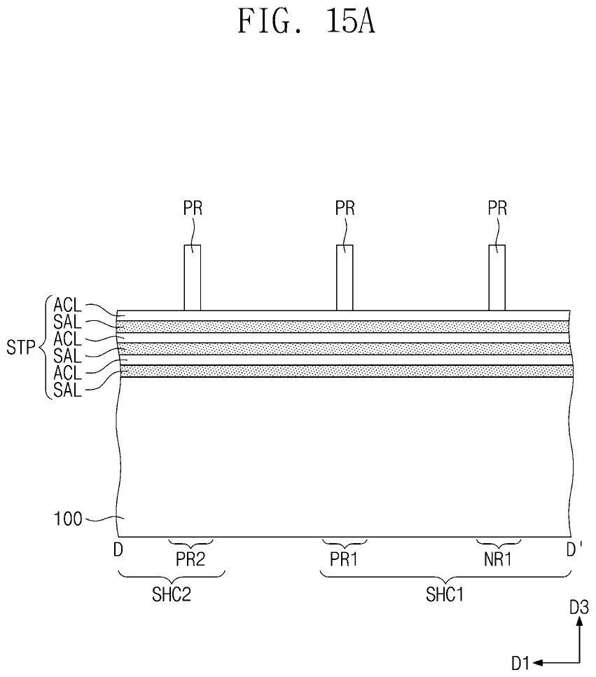

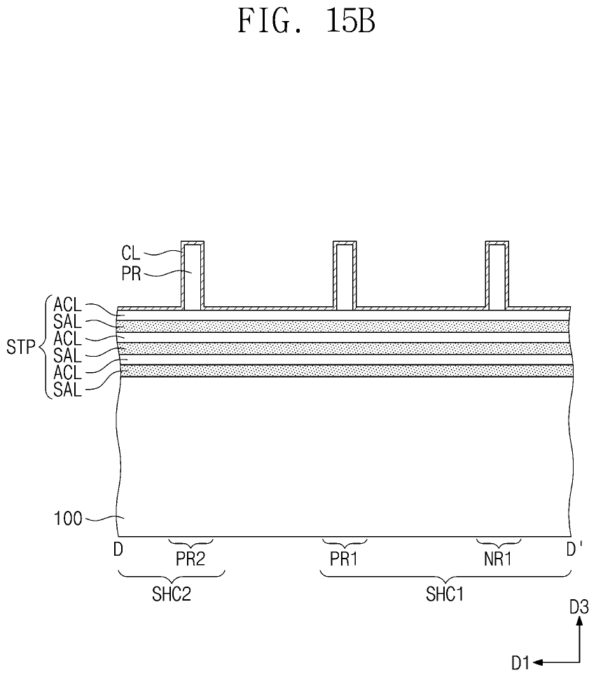

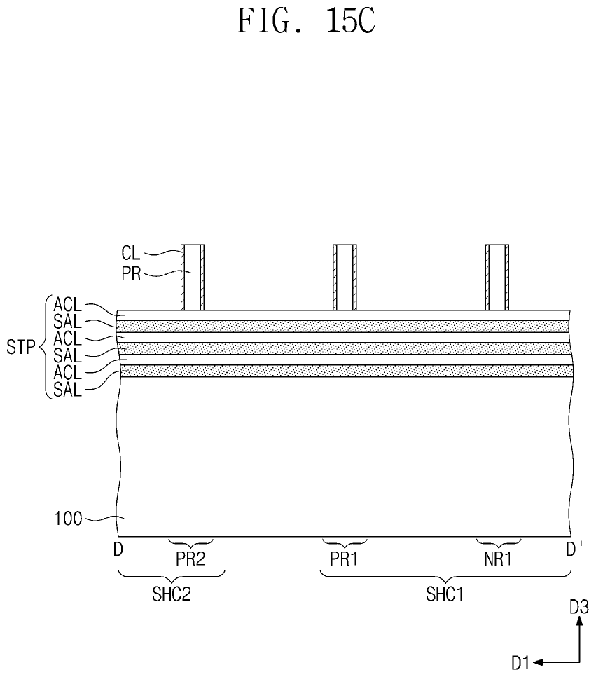

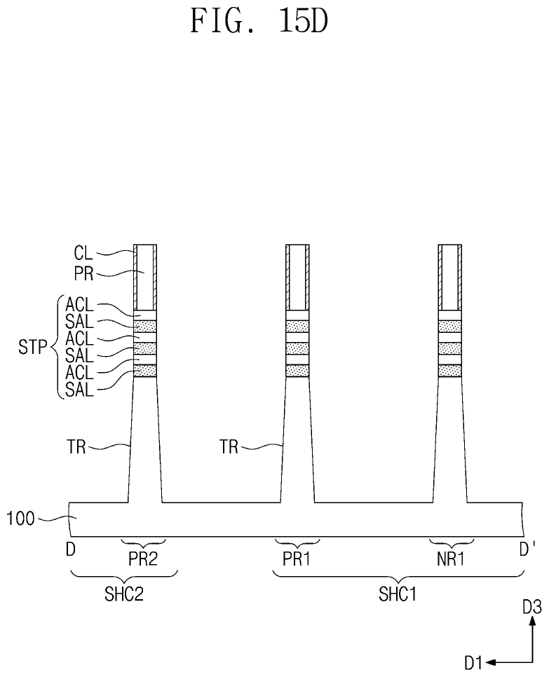

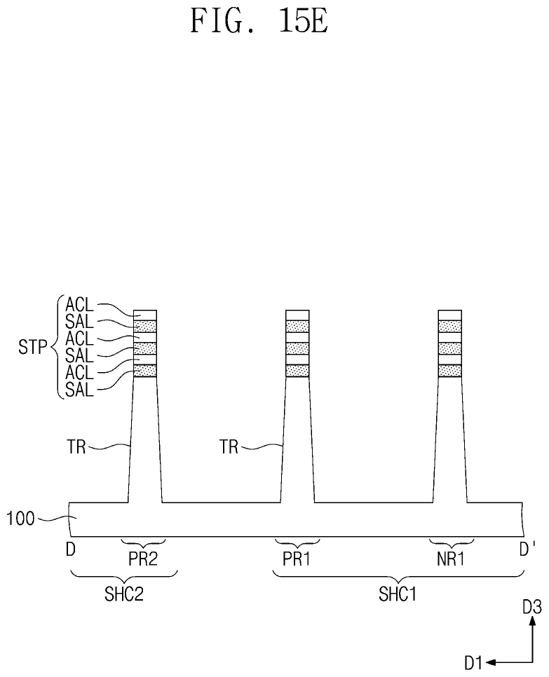

FIGS. 15A to 15E are cross-sectional views illustrating a method of forming the first and second active patterns AP1 and AP2 of FIG. 8B. FIGS. 15A, 15B, 15C, 15D, and 15E are cross-sectional views taken along line D-D′ of FIG. 6.

Referring to FIGS. 15A and 15B, a photoresist pattern PR may be formed on the stacked pattern STP. The photoresist pattern PR may have a line shape or a bar shape extending in the second direction D2. A liner layer CL may be formed on the photoresist pattern PR and the stacked pattern STP. The liner layer CL may cover both sidewalls and an upper surface of the photoresist pattern PR. That is, the liner layer CL may be conformally formed on the entire surface of the substrate 100. In some embodiments, the liner layer CL may have a uniform thickness along a surface on which the liner layer CL is formed, as illustrated in FIG. 15B.

Forming the liner layer CL may include a photolithography method according to the embodiments described above with reference to FIGS. 1 to 5. Forming the liner layer CL may include a deposition process of reacting an initiator and a monomer with each other. Forming the liner layer CL may include an initiated chemical vapor deposition (iCVD) process.

The monomer may include multiple bonds between carbon atoms. The initiator may include a material that forms a radical by thermal decomposition. A copolymer may be formed by an initiation reaction between the radical and the monomer. The liner layer may include the copolymer. Each of the initiator and monomer may be the same as the initiator and monomer described above with reference to FIGS. 1 to 5.

Referring to FIG. 15C, the liner layer CL and the photoresist pattern PR may be etched back. As a result, a portion of the liner layer CL and a portion (e.g., an upper portion) of the photoresist pattern PR may be removed. In detail, only the liner layer CL covering the sidewall of the photoresist pattern PR may not be removed.

Referring to FIG. 15D, a patterning process may be performed using the liner layer CL and the photoresist pattern PR as masks. The substrate 100 and the stacked pattern STP may be etched by the patterning process. The trench TR may be formed by the patterning process. The first and second active patterns AP1 and AP2 may be defined by the trench TR.

Referring to FIG. 15E, the liner layer CL and the photoresist pattern PR may be removed (e.g., simultaneously removed) by one etching process. To this end, in the etching process, the etching ratio of the liner layer CL to the photoresist pattern PR may be the same. In the etching process, the etching ratio of the liner layer CL to the photoresist pattern PR may be in a range of from 0.8 to 1.2. The etching process may be a dry etching process.

According to some embodiments of the inventive concept, as the liner layer CL and the photoresist pattern PR are removed by one etching process, it is possible to reduce or prevent an increase in a depth of the trench TR. In addition, as there is no additional etching process, a width of the trench TR may not increase further by the etching process. As a result, the inventive concept may improve reliability and precision of the semiconductor device.

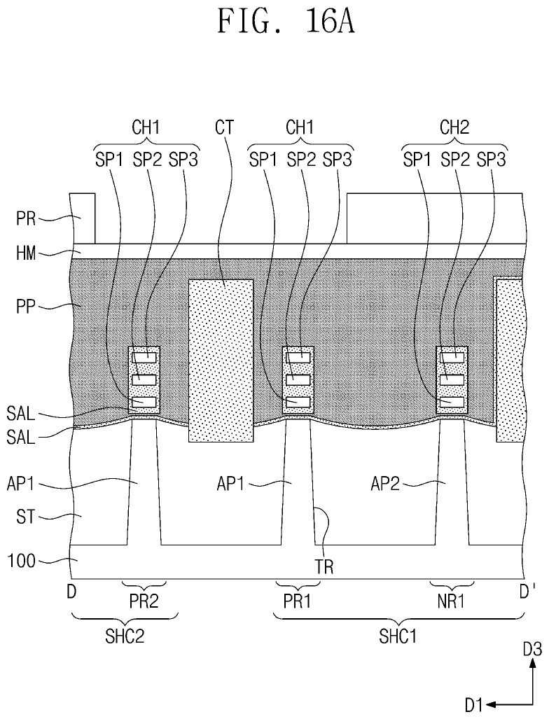

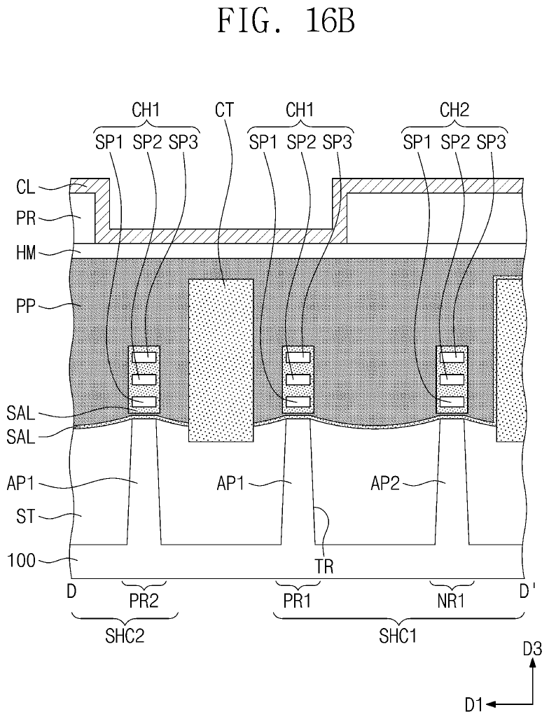

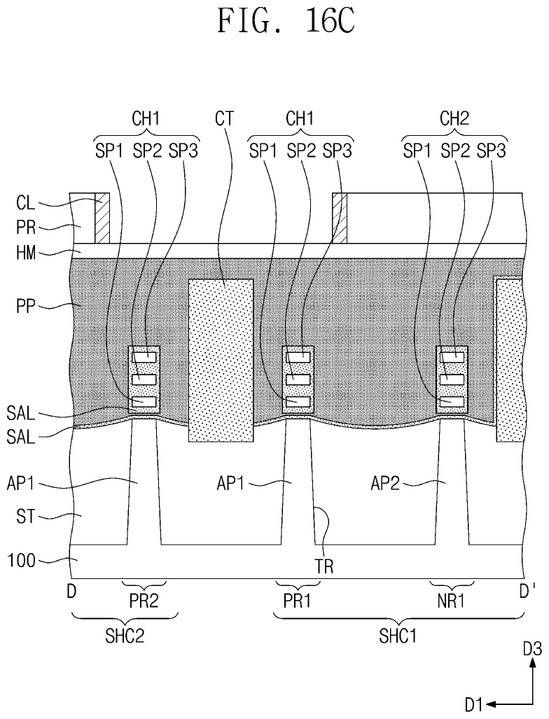

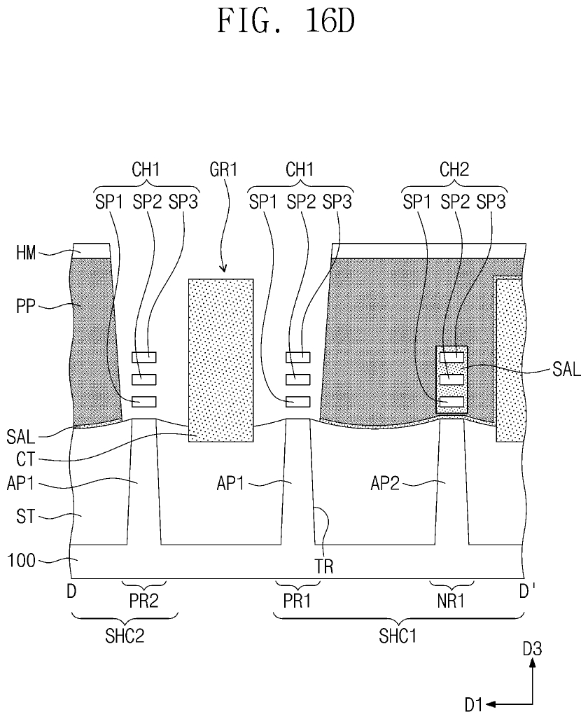

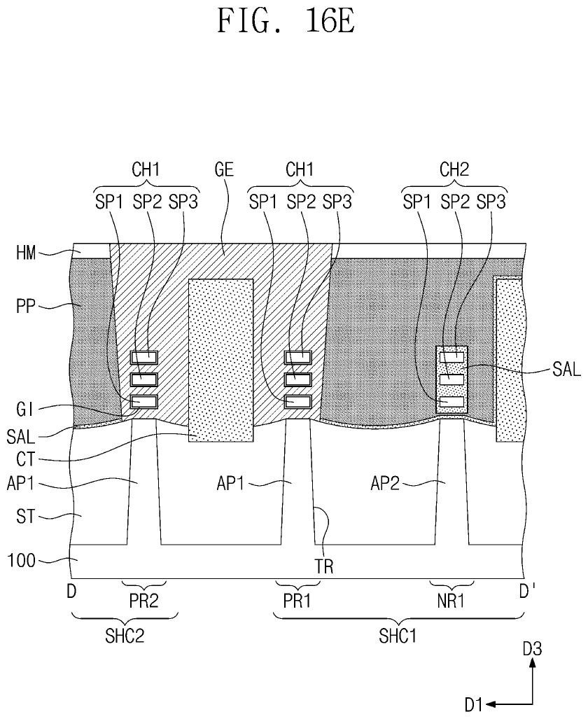

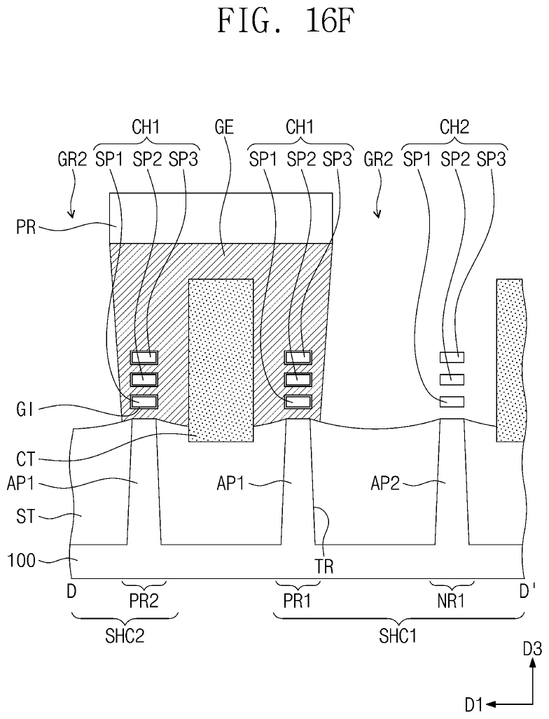

FIGS. 16A to 16F are cross-sectional views taken along line D-D′ of FIG. 6. FIGS. 16A to 16F are cross-sectional views illustrating a manufacturing method for the structure shown in FIG. 14D according to some other embodiments of the inventive concept.

Referring to FIG. 16A, a hard mask HM may be formed on the sacrificial pattern PP. A photoresist pattern PR may be formed on the hard mask HM. The photoresist pattern PR may be formed on the first and second NMOSFET regions NR1 and NR2 and may not be formed on the first and second PMOSFET regions PR1 and PR2. Alternatively, the photoresist pattern PR may be formed on the first and second PMOSFET regions PR1 and PR2 and may not be formed on the first and second NMOSFET regions NR1 and NR2.

The sacrificial layers SAL may surround the first to third semiconductor patterns SP1, SP2, and SP3. The sacrificial layers SAL may be formed between the first to third semiconductor patterns SP1, SP2, and SP3, respectively. The sacrificial layers SAL may also be formed on the device isolation layer ST. The sacrificial layers SAL may be the same as the sacrificial layers SAL described above with reference to FIGS. 8A and 8B.

Referring to FIG. 16B, a liner layer CL may be conformally formed on the photoresist pattern PR and the hard mask HM. The liner layer CL may cover both sidewalls and an upper surface of the photoresist pattern PR. Forming the liner layer CL may include the photolithography method previously described with reference to FIGS. 1 to 5. Forming the liner layer CL may include an initiated chemical vapor deposition (iCVD) process.

Referring to FIG. 16C, the liner layer CL and the photoresist pattern PR may be etched back. As a result, a portion of the liner layer CL and a portion (e.g., an upper portion) of the photoresist pattern PR may be removed. In detail, the liner layer CL covering the sidewall of the photoresist pattern PR may not be removed.

Referring to FIG. 16D, a patterning process may be performed using the liner layer CL and the photoresist pattern PR as a mask. Through the patterning process, the hard mask HM and the sacrificial pattern PP may be etched and removed. Through the patterning process, a first gate recess GR1 exposing the first channel pattern CH1 and the gate cutting pattern CT may be formed. The sacrificial layers SAL exposed by the first gate recess GR1 may be removed.

The liner layer CL and the photoresist pattern PR may be removed (e.g., simultaneously removed) by one etching process. In the etching process, the etching ratio of the liner layer CL to the photoresist pattern PR may be the same. In the etching process, the etching ratio of the liner layer CL to the photoresist pattern PR may be in a range of from 0.8 to 1.2. The etching process may be a dry etching process.

Referring to FIG. 16E, after the sacrificial layers SAL are removed, a gate insulating layer GI may be conformally formed on the first channel pattern CH1. A gate electrode GE may be formed on the gate insulating layer GI. The gate electrode GE may fill the first gate recess GR1.

Referring to FIG. 16F, a photoresist pattern PR may be formed on the gate electrode GE again. An etching process using the photoresist pattern PR as a mask may be performed to remove all of the sacrificial patterns PP on the first and second NMOSFET regions NR1 and NR2, and thus the second channel pattern CH2 may be exposed by the second gate recess GR2. The second channel pattern CH2 may be exposed by the second gate recess GR2.

Referring to FIG. 14D, a gate insulating layer GI may be conformally formed on the second channel pattern CH2. A gate electrode GE may be formed on the gate insulating layer GI. The gate electrode GE on the first and second PMOSFET regions PR1 and PR2 may be formed of a different metal material from the gate electrode GE on the first and second NMOSFET regions NR1 and NR2.

Referring to FIGS. 16A to 16F, it may be seen that the gate electrode GE is formed on each of the first and second PMOSFET regions PR1 and PR2 and each of the first and second NMOSFET regions NR1 and NR2. As the gate electrode GE on each of the first and second PMOSFET regions PR1 and PR2 and the gate electrode GE on each of the first and second NMOSFET regions NR1 and NR2 are formed separately, the sacrificial pattern PP of the desired region should be etched. In the photolithography method according to some embodiments of the inventive concept, the photoresist pattern PR and the liner layer CL may be removed at the same time, and thus the widths of the first and second gate recesses GR1 and GR2 may not increase during the process of etching the sacrificial pattern PP. That is, as there is no additional etching process, the widths of the first and second gate recesses GR1 and GR2 may not increase. As a result, as only the desired region is etched, reliability and precision of the semiconductor device may be improved.

In the photolithography method according to some embodiments of the inventive concept, the liner layer may be conformally formed on the substrate and the photoresist pattern, and the etching rate of the liner layer may be similar to that of the photoresist pattern. The liner layer and the photoresist pattern may be removed (e.g., simultaneously removed) in one etching process. Accordingly, the precision and accuracy of the photolithography process may be improved. As a result, the inventive concept may improve the reliability of the semiconductor device.

As used herein, an element or region that is “covering” or “filling” another element or region may completely or partially cover or fill the other element or region. Further, the term “and/or” includes any and all combinations of one or more of the associated listed items.

While some example embodiments are described above, a person skilled in the art may understand that many modifications and variations are made without departing from the scope of the inventive concept defined in the following claims. Accordingly, the example embodiments of the inventive concept should be considered in all respects as illustrative and not restrictive, with the scope of the inventive concept being indicated by the appended claims.

What is claimed is:

1. A photolithograph method comprising:
forming a photoresist pattern on a substrate; and
conformally forming a liner layer on the photoresist pattern,
wherein the forming of the liner layer includes a deposition process of reacting an initiator and a monomer with each other,
wherein the monomer includes multiple bonds between carbon atoms,
wherein the initiator includes a material that forms a radical by thermal decomposition,
wherein a copolymer is formed by an initiating reaction between the radical and the monomer, and
wherein the liner layer includes the copolymer.

2. The photolithography method of claim 1, wherein (a partial pressure of the monomer)/(a saturation pressure of the monomer) is in a range of from 0.01 to 0.2.

3. The photolithography method of claim 1, further comprising:
etching back the liner layer and the photoresist pattern after forming the liner layer to remove a portion of the liner layer and a portion of the photoresist pattern;
performing a patterning process using the liner layer and the photoresist pattern as a mask; and
removing the liner layer and the photoresist pattern.

4. The photolithography method of claim 3, wherein the photoresist pattern and the liner layer are removed by a single etching process.

5. The photolithography method of claim 4,
wherein, in the etching process, an etching ratio of the liner layer to the photoresist pattern is in a range of from 0.8 to 1.2.

6. The photolithography method of claim 1,
wherein the forming of the liner layer includes an initiated chemical vapor deposition process (iCVD).

7. The photolithography method of claim 1, wherein the initiator includes a compound of Formula 1: 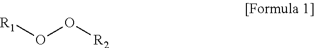
wherein R1 and R2 are each independently an alkyl group having 1 to 5 carbon atoms, an alkynyl group having 2 to 15 carbon atoms, or a substituted or unsubstituted carbonyl group.

8. The photolithography method of claim 1, wherein the monomer includes a compound of Formula 2: 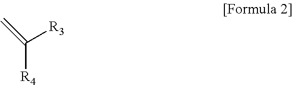
wherein R3 and R4 are each independently hydrogen, an alkyl group having 1 to 15 carbon atoms, an alkynyl group having 1 to 15 carbon atoms, an aryl group having 1 to 15 carbon atoms, a substituted or unsubstituted carboxyl group, a substituted or unsubstituted carbonyl group, or a substituted or unsubstituted alkoxy group.

9. The photolithography method of claim 1,
wherein the initiator includes at least one of tert-butyl peroxide (TBPO), tert-amylperoxide, tert-butykperoxybenzoate, and perfluorooctanesulfonyl fluoride.

10. The photolithography method of claim 1,
wherein the monomer includes at least one of divinylbenzene (DVB), cyclohexyl methacrylate, glycidyl methacrylate, hydroxyethyl methacrylate, 2-Hydroxyethyl acrylate (HEA), methacrylic anhydride, ethylene glycol dimethacrylate, 1,3-butanediol diacrylate, 1,3,5,7-tetravinyl-3,5,7-tetramethyl, vinylimidazole, acrylic acid, N-vinyl-2-pyrrolidone, and 1H, 1H,2H,2H-perfluorodecyl methacrylate.

11. A method of manufacturing a semiconductor device, the method comprising:
forming a photoresist pattern on a substrate;
heating the substrate;
conformally forming a liner layer on the substrate and the photoresist pattern;
etching back the liner layer and the photoresist pattern to remove a portion of the liner layer and a portion of the photoresist pattern;
performing a patterning process using the liner layer and the photoresist pattern as a mask; and
removing the liner layer and the photoresist pattern by performing an etching process,
wherein the forming of the liner layer includes a deposition process of reacting an initiator and a monomer with each other,
wherein the monomer includes multiple bonds between carbon atoms,
wherein the initiator includes a material that forms a radical by thermal decomposition,
wherein a copolymer is formed by an initiating reaction between the radical and the monomer, and
wherein the liner layer includes the copolymer.

12. The method of claim 11, wherein (a partial pressure of the monomer)/(a saturation pressure of the monomer) is in a range of from 0.01 to 0.2.

13. The method of claim 11, wherein, in the etching process, an etching ratio of the liner layer to the photoresist pattern is in a range of from 0.8 to 1.2.

14. The method of claim 11, wherein the initiator includes a compound of Formula 1: 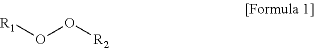
wherein each of R1 and R2 is an alkyl group having 1 to 5 carbon atoms, an alkynyl group having 2 to 15 carbon atoms, or a substituted or unsubstituted carbonyl group.

15. The method of claim 11, wherein the monomer includes a compound of Formula 2: 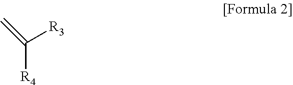
where each of R3 and R4 is hydrogen, an alkyl group having 1 to 15 carbon atoms, an alkynyl group having 1 to 15 carbon atoms, an aryl group having 1 to 15 carbon atoms, a substituted or unsubstituted carboxyl group, a substituted or unsubstituted carbonyl group, or a substituted or unsubstituted alkoxy group.

16. The method of claim 11, wherein the initiator includes at least one of tert-butyl peroxide (TBPO), tert-amylperoxide, tert-butykperoxybenzoate, and perfluorooctanesulfonyl fluoride.

17. The method of claim 11, wherein the monomer includes at least one of divinylbenzene (DVB), cyclohexyl methacrylate, glycidyl methacrylate, hydroxyethyl methacrylate, 2-Hydroxyethyl acrylate (HEA), methacrylic anhydride, ethylene glycol dimethacrylate, 1,3-butanediol diacrylate, 1,3,5,7-tetravinyl-1,3,5,7-tetramethyl, vinylimidazole, acrylic acid, N-vinyl-2-pyrrolidone, and 1H,1H,2H,2H-perfluorodecyl methacrylate.

18. A method of manufacturing a semiconductor device, the method comprising:
forming a stacked pattern on a substrate, the stacked pattern including active layers and sacrificial layers alternately stacked with each other;
forming a mask pattern on the substrate;
heating the substrate to form a liner layer covering the substrate and the mask pattern;
etching back the liner layer and the mask pattern to remove a portion of the liner layer and a portion of the mask pattern;
performing a patterning process using the liner layer and the mask pattern as a mask to form a trench in the substrate, the trench defining an active pattern; and
removing the liner layer and the mask pattern,
wherein the forming of the liner layer includes a deposition process of reacting an initiator and a monomer with each other,
wherein the monomer includes multiple bonds between carbon atoms,
wherein the initiator includes a material that forms a radical by thermal decomposition,
wherein a copolymer is formed by an initiating reaction between the radical and the monomer, and
wherein the liner layer includes the copolymer.

19. The method of claim 18, wherein (a partial pressure of the monomer)/(a saturation pressure of the monomer) is in a range of from 0.01 to 0.2.

20. The method of claim 18, wherein, in the removing of the liner layer and the mask pattern, an etching ratio of the liner layer to the mask pattern is in a range of from 0.8 to 1.2.
